(19) United States
(12) Patent Application Publication
(10) Pub. No.: US 2024/0230720 A1
(43) Pub. Date: Jul. 11, 2024

(54) DETECTION DEVICE AND DETECTION METHOD

(71) Applicant: MEDIATEK INC., Hsinchu City (TW)

(72) Inventors: Long-Kun YU, Hsinchu City (TW); Zi-Ren LIU, Hsinchu City (TW); Ching-Wen CHENG, Hsinchu City (TW); Hsun-Wei PAO, Hsinchu City (TW); Wai-Ling CHENG, Singapore (SG); Ping CHEN, Hsinchu City (TW); Jie-Fan LAI, Hsinchu City (TW); Yeng-Ming TZENG, Hsinchu City (TW); Hung-Chuan CHEN, Hsinchu City (TW); Chia-Hua CHOU, Hsinchu City (TW); Bing-Shiun WANG, Hsinchu City (TW); Chia-Lung CHUANG, Hsinchu City (TW); Duen-Yi HO, Hsinchu City (TW); Che-Chi HUANG, Hsinchu City (TW)

(21) Appl. No.: 18/150,587

(22) Filed: Jan. 5, 2023

(51) Int. Cl. G01R 15/14

(52) U.S. Cl. CPC G01R 15/144

(57) ABSTRACT

A detection device includes a substrate and a die. The substrate provides a first voltage. The die is disposed adjacent to the substrate. The die includes a plurality of resistor paths, a selection circuit, an ADC (Analog-to-Digital Converter), and a digital circuit. The selection circuit selects one of the resistor paths as a target path. The target path provides a second voltage. The ADC generates a digital signal according to the first voltage and the second voltage. The digital circuit processes the digital signal.

### BACKGROUND OF THE INVENTION

### Field of the Invention

The disclosure generally relates to a detection device, and more specifically, to a detection device and a detection method.

### Description of the Related Art

Generally, operational characteristics of a conventional chip cannot be easily detected. For example, when the conventional chip is measured, it should be coupled to an external oscilloscope, which is expensive and not convenient for users. Accordingly, there is a need to propose a novel solution for solving the problems of the prior art.

### BRIEF SUMMARY OF THE INVENTION

In an exemplary embodiment, the disclosure is directed to a detection device that includes a substrate and a die. The substrate provides a first voltage. The die is disposed adjacent to the substrate. The die includes a plurality of resistor paths, a selection circuit, an ADC (Analog-to-Digital Converter), and a digital circuit. The selection circuit selects one of the resistor paths as a target path. The target path provides a second voltage. The ADC generates a digital signal according to the first voltage and the second voltage. The digital circuit processes the digital signal.

In some embodiments, the detection device is a power sensor on a flip chip package.

In some embodiments, the substrate further includes a substrate pad for outputting the first voltage.

In some embodiments, the die further includes an I/O (Input/Output) bump coupled to the substrate pad.

In some embodiments, the ADC has a first input terminal coupled to the I/O bump for receiving the first voltage.

In some embodiments, the ADC further has a second input terminal coupled through the selection circuit to the target path for receiving the second voltage.

In some embodiments, the ADC further has an output terminal for outputting the digital signal to the digital circuit.

In some embodiments, the selection circuit is implemented with a multiplexer.

In some embodiments, the resistor paths are implemented with a plurality of metal layers in the die.

In some embodiments, the digital signal is determined according to a voltage difference between the first voltage and the second voltage.

In another exemplary embodiment, the disclosure is directed to a detection method that includes the following steps: receiving a first voltage from a substrate; selecting one of a plurality of resistor paths of a die as a target path via a selection circuit; receiving a second voltage from the target path; generating a digital signal according to the first voltage and the second voltage via an ADC; and processing the digital signal.

In an exemplary embodiment, the invention is directed to a detection device that includes a substrate and a die. The substrate includes a bottom portion and a top portion. The bottom portion of the substrate provides a first voltage. The top portion of the substrate provides a second voltage. The die is disposed adjacent to the substrate. The die includes an ADC and a digital circuit. The ADC generates a digital signal according to the first voltage and the second voltage. The digital circuit processes the digital signal.

In some embodiments, the bottom portion of the substrate is implemented with a bottom metal layer.

In some embodiments, the substrate further includes a first substrate pad and a second substrate pad disposed on the top portion.

In some embodiments, the die further includes a first I/O bump coupled through the first substrate pad to the bottom metal layer, and a second I/O bump coupled to the second substrate pad.

In some embodiments, an equivalent resistor is formed between the bottom portion and the top portion of the substrate.

In some embodiments, the resistance of the equivalent resistor is smaller than 1Ω.

In another exemplary embodiment, the invention is direct a detection method that includes the steps of: receiving a first voltage from a bottom portion of a substrate; receiving a second voltage from a top portion of the substrate; generating a digital signal according to the first voltage and the second voltage via an ADC; and processing the digital signal.

### BRIEF DESCRIPTION OF DRAWINGS

The invention can be more fully understood by reading the subsequent detailed description and examples with references made to the accompanying drawings, wherein:

FIG. 1 is a diagram of a detection device according to an embodiment of the invention;

FIG. 2 is a diagram of a detection device according to an embodiment of the invention;

FIG. 3 is a diagram of a detection device according to an embodiment of the invention;

FIG. 4 is a diagram of a detection device according to an embodiment of the invention;

FIG. 5 is a flowchart of a detection method according to an embodiment of the invention; and

FIG. 6 is a flowchart of a detection method according to an embodiment of the invention.

### DETAILED DESCRIPTION OF THE INVENTION

In order to illustrate the purposes, features and advantages of the invention, the embodiments and figures of the invention will be described in detail as follows.

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. The term “substantially” means the value is within an acceptable error range. One skilled in the art can solve the technical problem within a predetermined error range and achieve the proposed technical performance. Also, the term “couple” is intended to mean either an indirect or direct electrical connection. Accordingly, if one device is coupled to another device, that connection may be made through a direct electrical connection, or through an indirect electrical connection via other devices and connections.

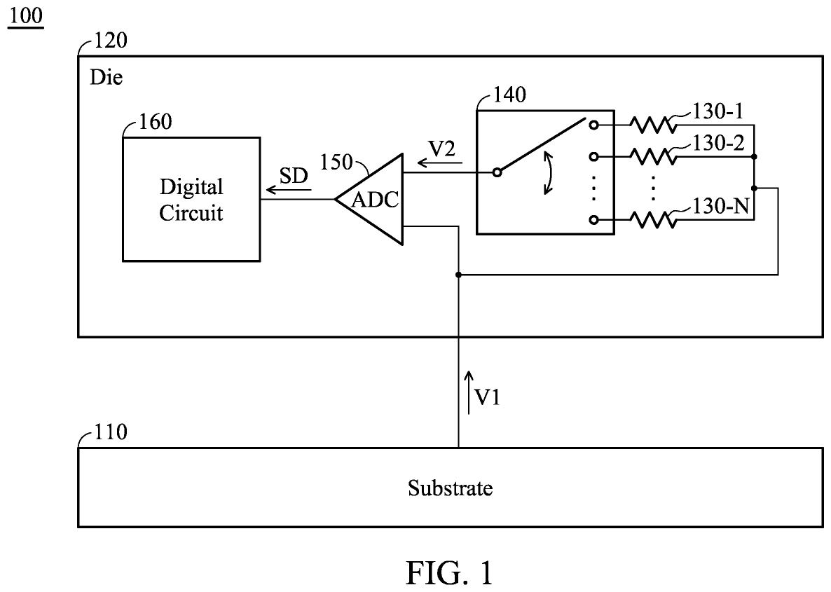

FIG. 1 is a diagram of a detection device 100 according to an embodiment of the invention. The detection device 100 may be applied to a mobile platform, such as a smart phone, a tablet computer, or a notebook computer. As shown in FIG. 1, the detection device 100 at least includes a substrate 110 and a die 120. It should be understood that the detection device 100 may include other components, such as a processor, a power supply module, a touch control panel, and/or a housing, although they are not displayed in FIG. 1. In some embodiments, the detection device 100 is a power sensor on a flip chip package, but it is not limited thereto.

For example, the substrate 110 may be a PCB (Printed Circuit Board) or an FPC (Flexible Printed Circuit). The substrate 110 can provide a first voltage V1. The die 120 is disposed adjacent to the substrate 110. It should be noted that the term “adjacent” or “close” over the disclosure means that the distance (spacing) between two corresponding elements is smaller than a predetermined distance (e.g., 10 mm or the shorter), or means that the two corresponding elements directly touch each other (i.e., the aforementioned distance/spacing between them is reduced to 0).

The die 120 includes a plurality of resistor paths 130-1, 130-2, . . . , and 130-N, a selection circuit 140, an ADC (Analog-to-Digital Converter) 150, and a digital circuit 160, where “N” is any positive integer greater than or equal to 2. The selection circuit 140 can select one of the resistor paths 130-1, 130-2, . . . , and 130-N as a target path. The selected target path is coupled through the selection circuit 140 to the ADC 150, and it can provide a second voltage V2. The ADC 150 can generate a digital signal SD according to the first voltage V1 and the second voltage V2. The digital circuit 160 can process the digital signal SD. In some embodiments, the selection circuit 140 selects the resistor paths 130-1, 130-2, . . . , and 130-N one after another. In some embodiments, the sampling rate of the ADC 150 is greater than or equal to 10 MHz, but it is not limited thereto.

With such a design, the digital circuit 160 can obtain the operational information of the substrate 110 and the resistor paths 130-1, 130-2, . . . , and 130-N by analyzing the digital signal SD. It is not necessary to use an external device for detection, such as an oscilloscope. Therefore, the proposed detection device 100 is inexpensive and more convenient for users.

The following embodiments will introduce the detailed structures and operations of the detection device 100. It should be understood that these figures and descriptions are merely exemplary, rather than limitations of the invention.

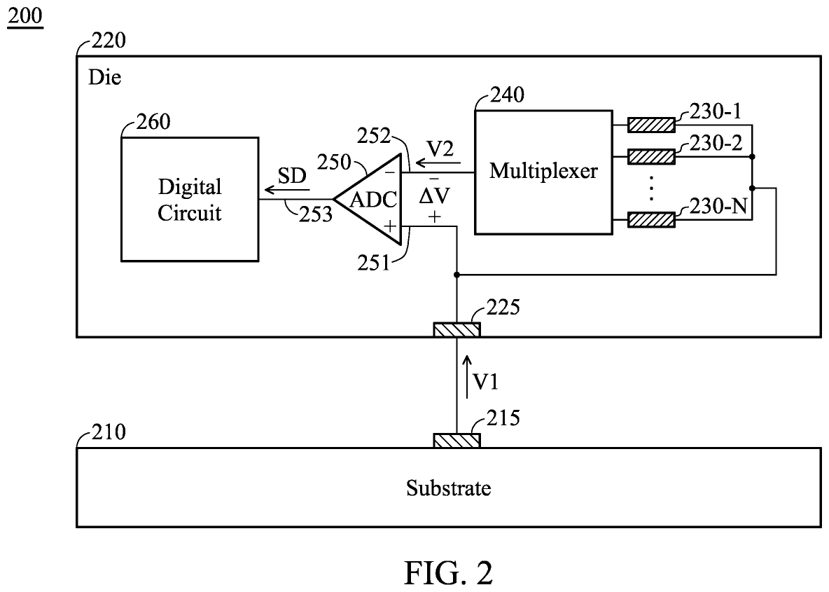

FIG. 2 is a diagram of a detection device 200 according to an embodiment of the invention. FIG. 2 is similar to FIG. 1. In the embodiment of FIG. 2, the detection device 200 at least includes a substrate 210 and a die 220. The die 220 includes an I/O (Input/Output) bump 225, a plurality of metal layers 230-1, 230-2, . . . , and 230-N, a multiplexer 240, an ADC 250, and a digital circuit 260. That is, the aforementioned resistor paths are implemented with the metal layers 230-1, 230-2, . . . , and 230-N of the die 220. Also, the aforementioned selection circuit is implemented with the multiplexer 240. In some embodiments, the metal layers 230-1, 230-2, . . . , and 230-N are considered as a variety of metal meshes distributed inside the die 220.

Specifically, the substrate 210 further includes a substrate pad 215 for outputting a first voltage V1. The I/O bump 225 of the die 220 is coupled to the substrate pad 215 of the substrate 210. The multiplexer 240 can select one of the metal layers 230-1, 230-2, . . . , and 230-N, and then the selected metal layer can provide a second voltage V2. The ADC 250 has a first input terminal 251 coupled to the I/O bump 225 for receiving the first voltage V1, a second input terminal 252 coupled through the multiplexer 240 (i.e., the aforementioned selection circuit) to the selected metal layer (i.e., the aforementioned target path) for receiving the second voltage V2, and an output terminal 253 for outputting a digital signal SD to the digital circuit 260.

In some embodiments, the first input terminal 251 of the ADC 250 is a positive input terminal, and the second input terminal 252 of the ADC 250 is a negative input terminal. However, the invention is not limited thereto. In alternative embodiments, the first input terminal 251 of the ADC 250 is a negative input terminal, and the second input terminal 252 of the ADC 250 is a positive input terminal.

In some embodiments, the digital signal SD is determined according to a voltage difference ΔV between the first voltage V1 and the second voltage V2. If the resistances of the metal layers 230-1, 230-2, . . . , and 230-N are known, the digital circuit 260 can process the digital signal SD to obtain the voltage difference ΔV and the corresponding current.

Therefore, the digital circuit 260 can calculate the power consumption without using any external device. Other features of the detection device 200 of FIG. 2 are similar to those of the detection device 100 of FIG. 1. Therefore, the two embodiments can achieve similar levels of performance.

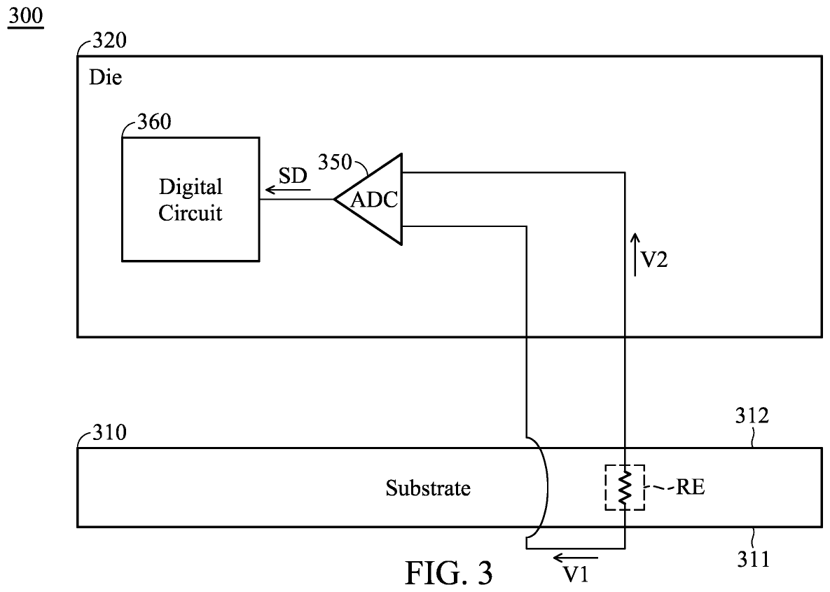

FIG. 3 is a diagram of a detection device 300 according to an embodiment of the invention. FIG. 3 is similar to FIG. 1. In the embodiment of FIG. 3, the detection device 300 at least includes a substrate 310 and a die 320. The substrate 310 includes a bottom portion 311 and a top portion 312. The bottom portion 311 of the substrate 310 can provide a first voltage V1. The top portion 312 of the substrate 310 can provide a second voltage V2. In addition, an equivalent resistor RE may be formed between the bottom portion 311 and the top portion 312 of the substrate 310. For example, the resistance of the equivalent resistor RE may be smaller than 1Ω. It is understood that the total resistance through the substrate 310 is modeled as the equivalent resistor RE, which may be a virtual resistor. In some embodiments, one terminal of the equivalent resistor RE is arranged to output the first voltage V1, and the other terminal of the equivalent resistor RE is arranged to output the second voltage V2.

The die 320 is disposed adjacent to the substrate 310. The die 320 includes an ADC 350 and a digital circuit 360. The ADC 350 can generate a digital signal SD according to the first voltage V1 and the second voltage V2. The digital circuit 360 can process the digital signal SD, so as to obtain the operational characteristics of the substrate 310. Other features of the detection device 300 of FIG. 3 are similar to those of the detection device 100 of FIG. 1. Therefore, the two embodiments can achieve similar levels of performance.

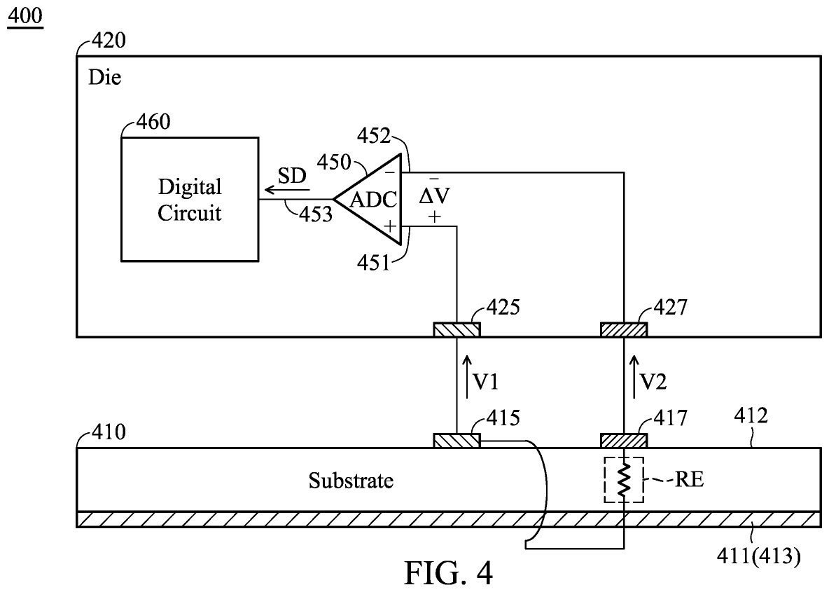

FIG. 4 is a diagram of a detection device 400 according to an embodiment of the invention. FIG. 4 is similar to FIG. 3. In the embodiment of FIG. 4, the detection device 400 at least includes a substrate 410 and a die 420. Specifically, the substrate 410 at least includes a bottom portion 411 and a top portion 412. The die 420 includes a first I/O bump 425, a second I/O bump 427, an ADC 450, and a digital circuit 460.

In some embodiments, the bottom portion 411 of the substrate 410 is implemented with a bottom metal layer 413, but it is not limited thereto. In some embodiments, the substrate 410 further includes a first substrate pad 415 and a second substrate pad 417 disposed on the top portion 412. The first I/O bump 425 of the die 420 is coupled through the first substrate pad 415 to the bottom metal layer 413 of the substrate 410. The second I/O bump 427 of the die 420 is coupled to the second substrate pad 417 of the substrate 410. For example, an equivalent resistor RE may be formed between the bottom portion 411 and the top portion 412 of the substrate 410. Also, a current path is formed from the first substrate pad 415 through the bottom metal layer 413 and equivalent resistor RE to the second substrate pad 417.

The ADC 250 has a first input terminal 451 coupled to the first I/O bump 425 for receiving the first voltage V1, a second input terminal 452 coupled to the second I/O bump 427 for receiving the second voltage V2, and an output terminal 453 for outputting a digital signal SD to the digital circuit 460. In some embodiments, the first input terminal 451 of the ADC 450 is a positive input terminal, and the second input terminal 452 of the ADC 450 is a negative input terminal. However, the invention is not limited thereto. In alternative embodiments, the first input terminal 451 of the ADC 450 is a negative input terminal, and the second input terminal 452 of the ADC 450 is a positive input terminal.

In some embodiments, the digital signal SD is determined according to a voltage difference ΔV between the first voltage V1 and the second voltage V2. If the resistance of the equivalent resistor RE is known, the digital circuit 460 can process the digital signal SD to obtain the voltage difference ΔV and the corresponding current. Therefore, the digital circuit 460 can calculate the power consumption without using any external device. Other features of the detection device 400 of FIG. 4 are similar to those of the detection device 300 of FIG. 3. Therefore, the two embodiments can achieve similar levels of performance.

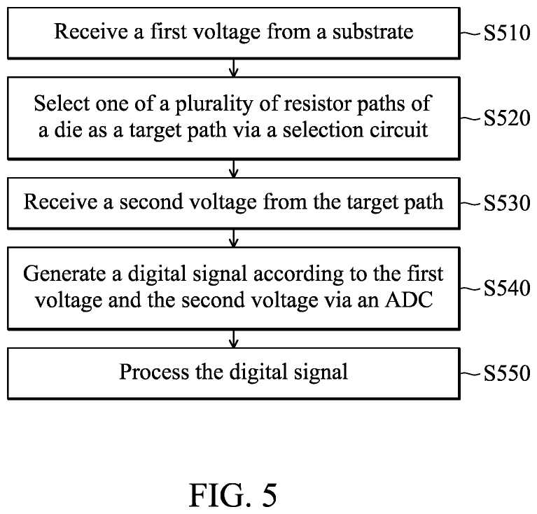

FIG. 5 is a flowchart of a detection method according to an embodiment of the invention. The aforementioned communication method includes the following steps. In step S510, a first voltage is received from a substrate. In step S520, one of a plurality of resistor paths of a die is selected as a target path via a selection circuit. In step S530, a second voltage is received from the target path. In step S540, a digital signal is generated according to the first voltage and the second voltage via an ADC. In step S550, the digital signal is processed. It should be noted that the above steps are not required to be performed in order, and all of the features of the embodiments of FIGS. 1 and 2 maybe applied to the detection method of FIG. 5.

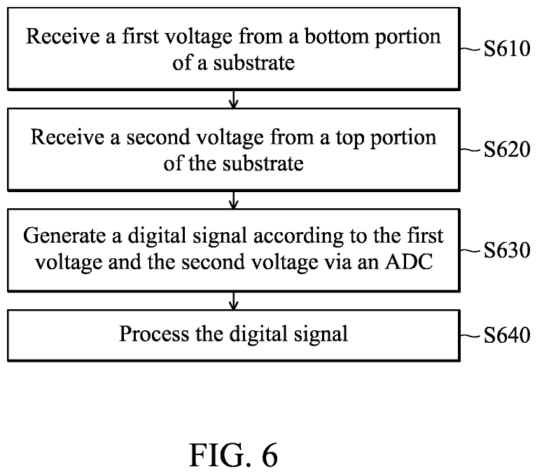

FIG. 6 is a flowchart of a detection method according to an embodiment of the invention. The aforementioned communication method includes the following steps. In step S610, a first voltage is received from a bottom portion of a substrate. In step S620, a second voltage is received from a top portion of the substrate. In step S630, a digital signal is generated according to the first voltage and the second voltage via an ADC. In step S640, the digital signal is processed. It should be noted that the above steps are not required to be performed in order, and all of the features of the embodiments of FIGS. 3 and 4 maybe applied to the detection method of FIG. 6.

The invention proposes a novel detection device and a detection method. Compared to the conventional design, the invention has at least the advantages of minimizing the design area, decreasing the manufacturing cost, and increasing the convenience of measurement, and therefore it is suitable for application in a variety of mobile communication devices.

Note that the above element parameters are not limitations of the invention. An designer can fine-tune these settings or values according to different requirements. It should be understood that the detection device and detection method of the invention are not limited to the configurations of FIGS. 1-6. The invention may merely include any one or more features of any one or more embodiments of FIGS. 1-6. In other words, not all of the features displayed in the figures should be implemented in the detection device and detection method of the invention.

The method of the invention, or certain aspects or portions thereof, may take the form of program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes an apparatus for practicing the methods. The methods may also be embodied in the form of program code transmitted over some transmission medium, such as electrical wiring or cabling, through fiber optics, or via any other form of transmission, wherein, when the program code is received and loaded into and executed by a machine such as a computer, the machine becomes an apparatus for practicing the disclosed methods. When implemented on a general-purpose processor, the program code combines with the processor to provide a unique apparatus that operates analogously to application-specific logic circuits.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A detection device, comprising:
a substrate, providing a first voltage; and
a die, disposed adjacent to the substrate, and comprising:
a plurality of resistor paths;
a selection circuit, selecting one of the resistor paths as a target path, wherein the target path provides a second voltage;
an ADC (Analog-to-Digital Converter), generating a digital signal according to the first voltage and the second voltage; and
a digital circuit, processing the digital signal.

2. The detection device as claimed in claim 1, wherein the detection device is a power sensor on a flip chip package.

3. The detection device as claimed in claim 1, wherein the substrate further comprises a substrate pad for outputting the first voltage.

4. The detection device as claimed in claim 3, wherein the die further comprises an I/O (Input/Output) bump coupled to the substrate pad.

5. The detection device as claimed in claim 4, wherein the ADC has a first input terminal coupled to the I/O bump for receiving the first voltage.

6. The detection device as claimed in claim 5, wherein the ADC further has a second input terminal coupled through the selection circuit to the target path for receiving the second voltage.

7. The detection device as claimed in claim 6, wherein the ADC further has an output terminal for outputting the digital signal to the digital circuit.

8. The detection device as claimed in claim 1, wherein the selection circuit is implemented with a multiplexer.

9. The detection device as claimed in claim 1, wherein the resistor paths are implemented with a plurality of metal layers in the die.

10. The detection device as claimed in claim 1, wherein the digital signal is determined according to a voltage difference between the first voltage and the second voltage.

11. A detection method, comprising the steps of:
receiving a first voltage from a substrate;
selecting one of a plurality of resistor paths of a die as a target path via a selection circuit;
receiving a second voltage from the target path;
generating a digital signal according to the first voltage and the second voltage via an ADC (Analog-to-Digital Converter); and
processing the digital signal.

12. The detection method as claimed in claim 11, wherein the digital signal is determined according to a voltage difference between the first voltage and the second voltage.

13. A detection device, comprising:
a substrate, comprising a bottom portion and a top portion, wherein the bottom portion provides a first voltage, and the top portion provides a second voltage; and
a die, disposed adjacent to the substrate, and comprising:
an ADC (Analog-to-Digital Converter), generating a digital signal according to the first voltage and the second voltage; and
a digital circuit, processing the digital signal.

14. The detection device as claimed in claim 13, wherein the bottom portion of the substrate is implemented with a bottom metal layer.

15. The detection device as claimed in claim 14, wherein the substrate further comprises a first substrate pad and a second substrate pad disposed on the top portion.

16. The detection device as claimed in claim 15, wherein the die further comprises a first I/O (Input/Output) bump coupled through the first substrate pad to the bottom metal layer, and a second I/O bump coupled to the second substrate pad.

17. The detection device as claimed in claim 13, wherein an equivalent resistor is formed between the bottom portion and the top portion of the substrate.

18. The detection device as claimed in claim 17, wherein a resistance of the equivalent resistor is smaller than 1Ω.

19. The detection device as claimed in claim 13, wherein the digital signal is determined according to a voltage difference between the first voltage and the second voltage.

20. A detection method, comprising the steps of:
receiving a first voltage from a bottom portion of a substrate;
receiving a second voltage from a top portion of the substrate;
generating a digital signal according to the first voltage and the second voltage via an ADC (Analog-to-Digital Converter); and
processing the digital signal.
